(19) United States
(12) Patent Application Publication
(10) Pub. No.: US 2014/0110793 A1
(43) Pub. Date: Apr. 24, 2014

(54) CMOS TRANSISTOR AND FABRICATION METHOD

(71) Applicant: SEMICONDUCTOR MANUFACTURING INTERNATIONAL CORP., Shanghai (CN)

(72) Inventor: ZHONGSHAN HONG, Shanghai (CN)

(73) Assignee: SEMICONDUCTOR MANUFACTURING INTERNATIONAL CORP., Shanghai (CN)

(21) Appl. No.: 13/792,298

(22) Filed: Mar. 11, 2013

(30) Foreign Application Priority Data
Oct. 22, 2012 (CN) 201210405792.1

(51) Int. Cl. H01L 21/8238; H01L 27/092

(52) U.S. Cl. CPC H01L 21/8238; H01L 27/092
USPC 257/369; 438/199

(57) ABSTRACT

Exemplary embodiments provide transistors and methods for forming the transistors. An exemplary CMOS transistor can be formed by epitaxially forming a first stress layer in/on a semiconductor substrate having a first region including a first gate structure and a second region including a second gate structure. A barrier layer can be formed to cover the second region and to expose the first region. The barrier layer can be used as a mask to remove a portion of the first stress layer from the first region. A second stress layer can be formed in a groove formed in the semiconductor substrate on sides of the first gate structure in the first region. The fabrication method can be simplified and the formed CMOS transistors can have high carrier mobility.

### CROSS-REFERENCES TO RELATED APPLICATIONS

This application claims the priority to Chinese Patent Application No. CN201210405792.1, filed on Oct. 22, 2012, which is incorporated herein by reference in its entirety.

### FIELD OF THE DISCLOSURE

The present disclosure relates to the field of semiconductor technology and, more particularly, relates to transistors and fabrication methods.

### BACKGROUND

With rapid development of semiconductor manufacturing technologies, the gate of complementary metal oxide semiconductor (CMOS) transistors has become increasingly thin in thickness and short in length. To achieve better electrical performance, device functions are often enhanced by controlling carrier mobility and, more specifically, by controlling stress generated in the channel region of the transistors.

Conventional methods for enhancing carrier mobility of transistors include stress memorization techniques (SMT) and embedded silicon germanium (SiGe) techniques. The embedded SiGe techniques may include forming a stress layer in a region that is to be used as a diffusion region, followed by doping the region to form source and drain regions of the transistors. Stress is generated in the channel region due to differences in crystal lattice structure of the materials used in the SiGe techniques. Carrier mobility in the channel region is then increased and device performance of the formed transistors is enhanced.

FIGS. 1-5 depict a conventional method for forming a CMOS transistor. In FIG. 1, a semiconductor substrate 100 is provided and includes an NMOS region I and a PMOS region II. The NMOS regional I is isolated from the PMOS region II by a shallow trench isolation structure 102. A first gate structure 101 is formed on surface of the semiconductor substrate 100 in the NMOS regional I. A second gate structure 103 is formed on the surface of the semiconductor substrate 100 in the PMOS region II.

In FIG. 2, a first photoresist layer 105 is formed to cover the PMOS regional II. In FIG. 3, a silicon carbide layer 107 is formed in the semiconductor substrate 100 in the NMOS region I. The silicon carbide layer 107 is doped with suitable impurity ions to form a source region and a drain region of the NMOS transistor.

In FIG. 4, after forming the silicon carbide layer 107, the first photoresist layer 105 is removed and a second photoresist layer 109 is formed to cover the NMOS region I.

In FIG. 5, a groove (not shown) is formed by etching the semiconductor substrate 100 in the PMOS region II. A silicon germanium layer 111 is then formed in the groove, followed by removing the second photoresist layer 109 (as shown in FIG. 4). Although the formed CMOS transistor may have increased carrier mobility in the channel region, at least two photoresist or like layers need to be used and such manufacturing process is complicated and need to be simplified.

Thus, there is a need to provide CMOS transistors with improved carrier mobility and methods for fabricating the CMOS transistors using a simplified process.

### BRIEF SUMMARY OF THE DISCLOSURE

According to various embodiments, there is provided a method for forming a CMOS transistor. A semiconductor substrate can be provided to include a first region and a second region. The first region can include a first gate structure formed on the semiconductor substrate and the second region can include a second gate structure formed on the semiconductor substrate. A first stress layer can be formed on the semiconductor substrate and on sides of each of the first gate structure and the second gate structure by a selective epitaxial deposition process. A barrier layer can be formed to cover the second gate structure and the first stress layer in the second region. The barrier layer can expose the first gate structure and a portion of the first stress layer in the first region. The portion of the first stress layer in the first region can then be removed using the barrier layer as a mask. A groove can be formed in the semiconductor substrate on each side of the first gate structure in the first region. A second stress layer can be formed in the groove.

According to various embodiments, there is provided a CMOS transistor. The CMOS transistor can include a semiconductor substrate, a first stress layer, and a second stress layer. The semiconductor substrate can include a first region having a first gate structure on the semiconductor substrate and a second region having a second gate structure on the semiconductor substrate. The first stress layer can be epitaxially disposed on sides of the second gate structure. The second stress layer can be disposed on sides of the first gate structure. The first stress layer and the second stress layer can be formed by a process including forming a stress layer on the semiconductor substrate and on the sides of each of the first gate structure and the second gate structure. A barrier layer can then be formed to cover the second gate structure and the stress layer in the second region and to expose the first gate structure and a portion of the stress layer in the first region. The portion of the stress layer in the first region can then be removed using the barrier layer as a mask. A remaining portion of the stress layer can form the first stress layer. The second stress layer can be formed in a groove formed in the semiconductor substrate on each side of the first gate structure in the first region.

It is to be understood that both the foregoing general description and the following detailed description are exemplary and explanatory only and are not restrictive of the invention, as claimed. Other aspects of the present disclosure can be understood by those skilled in the art in light of the description, the claims, and the drawings of the present disclosure.

### BRIEF DESCRIPTION OF THE DRAWINGS

FIGS. 1-5 depict cross-sectional views of a conventional CMOS transistor at various stages during its formation;

FIGS. 6-10 depict cross-sectional views of an exemplary CMOS transistor at various stages during its formation in accordance with various disclosed embodiments; and

FIG. 11 depicts an exemplary method for forming a CMOS transistor at various stages during its formation in accordance with various disclosed embodiments.

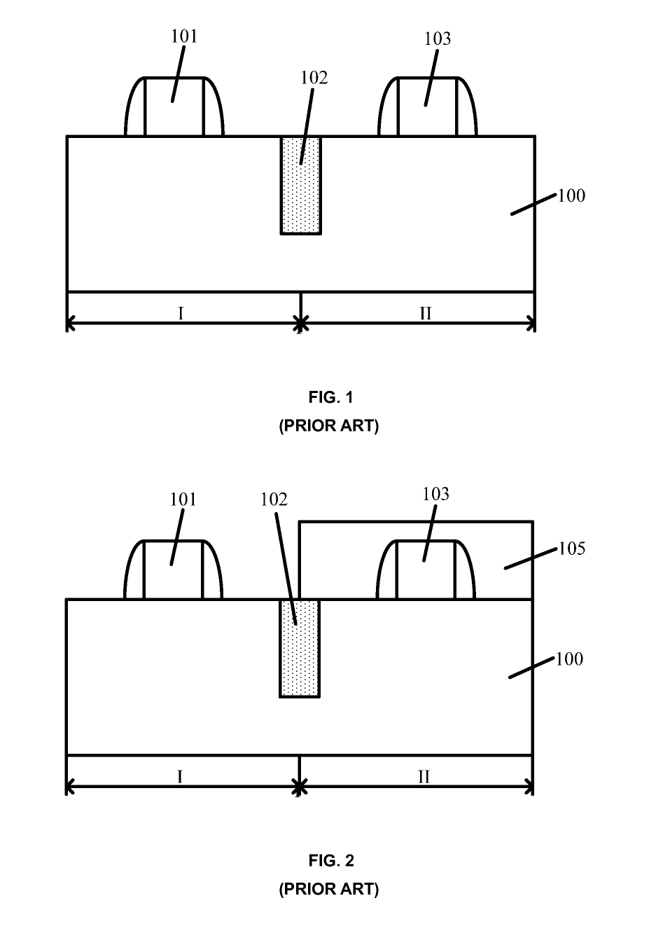

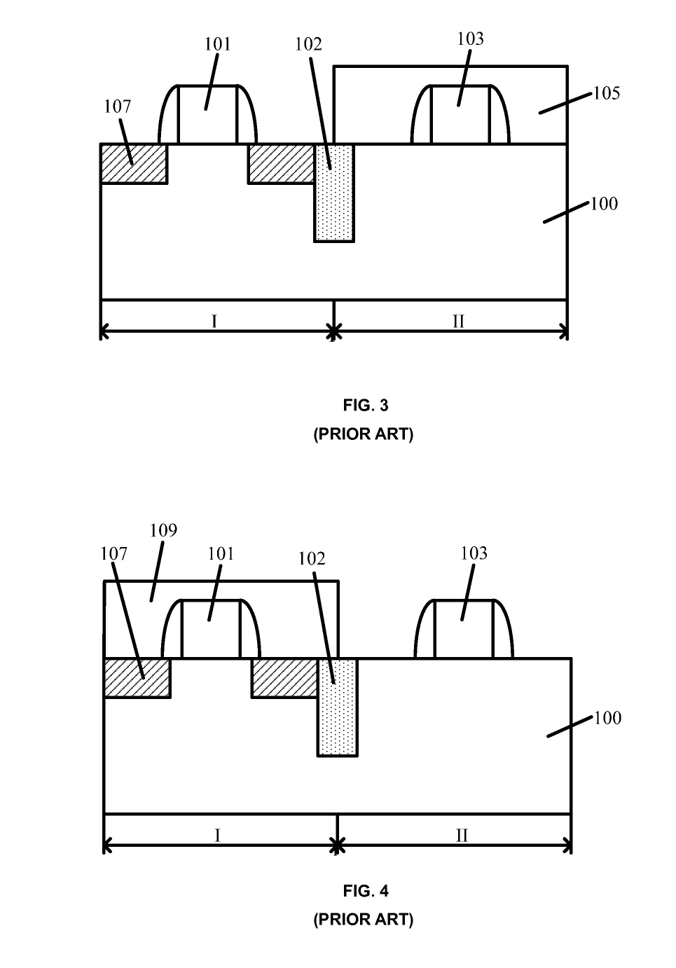

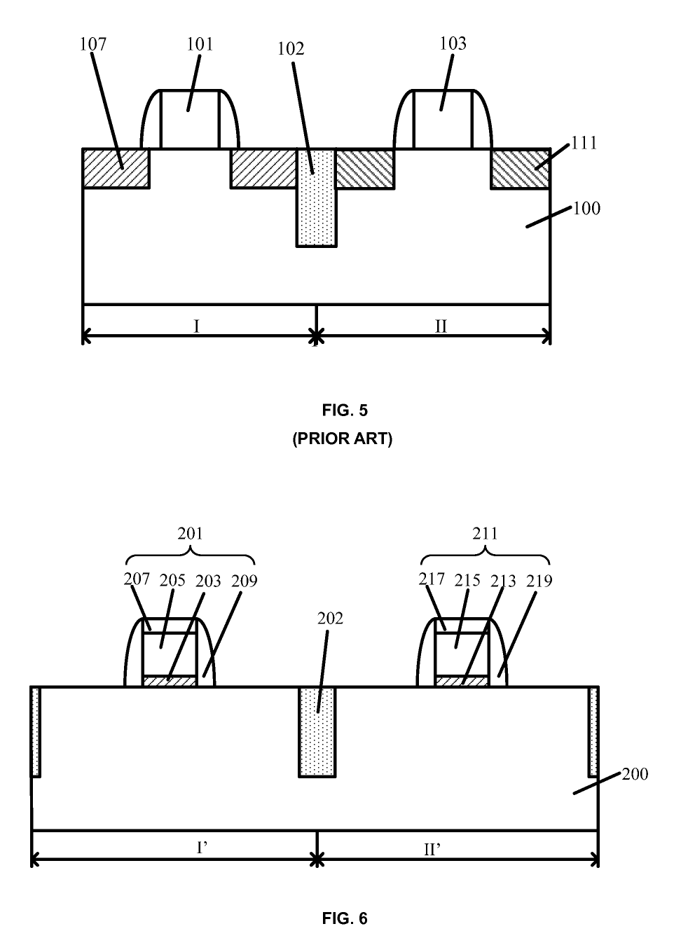

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

During formation of CMOS transistors, a stress layer is often formed in source and drain regions of the CMOS transistors. Photoresist layers are often required respectively in an NMOS region and a PMOS region as a mask for etching semiconductor substrate and for filling stress materials into the etched semiconductor substrate. Photoresist layers as etching masks are thus required for multiple times and each time the photoresist layer has to be formed first and removed later after certain processes have been performed. For this reason, multiple steps and complicated processes are used during formation of CMOS transistors.

The disclosed methods for forming CMOS transistors can involve a single time use of a mask (e.g., a barrier layer) to achieve formation of different stress layers in an NMOS region and a PMOS region. In addition, the exemplary barrier layer may or may not need to be removed. Manufacturing processes can thus be simplified with reduced manufacturing time.

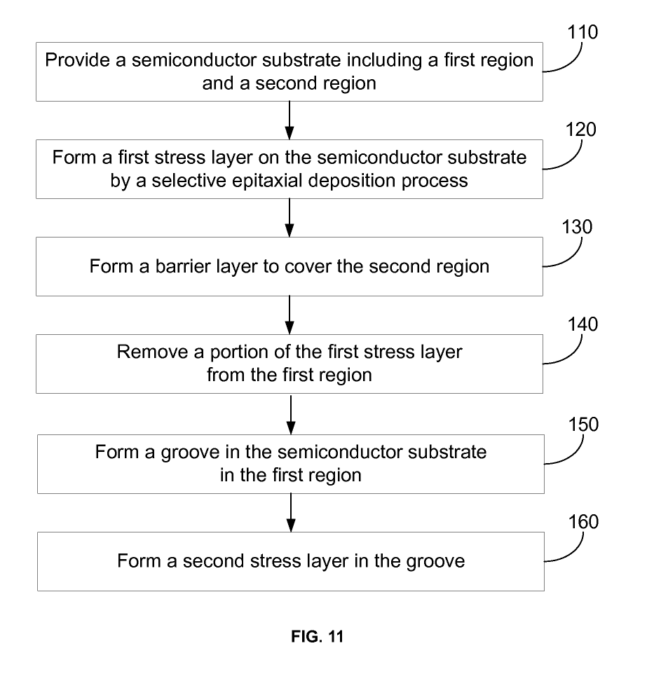

FIGS. 6-10 depict cross-sectional views of an exemplary CMOS transistor at various stages during its formation, while FIG. 11 depicts an exemplary method for forming a CMOS transistor at various stages during its formation in accordance with various disclosed embodiments. Note that although FIGS. 6-10 depict structures corresponding to the method depicted in FIG. 11, the structures and the method are not limited to each other in any manner.

In Step 110 of FIG. 11 and referring to FIG. 6 and, a semiconductor substrate 200 can be provided. The semiconductor substrate 200 can include a first region I′ and a second region II′. The first region I′ and the second region II′ can be adjacent to each other. A first gate structure 201 can be formed on the semiconductor substrate 200 in the first region I′ and a second gate structure 211 can be formed on the semiconductor substrate 200 in the second region II′.

The semiconductor substrate 200 can provide a platform for subsequent formation of the exemplary CMOS device. The semiconductor substrate 200 can be, e.g., a silicon (Si) substrate, a silicon-on-insulator (SOI) substrate, or other suitable substrates. The semiconductor substrate 200 can have a crystal orientation <110>, <100>, etc. The first region I′ and second region II′ can be used to form an NMOS transistor and a PMOS transistor, respectively, or vice versa.

The first region I′ and second region II′ can be isolated from each other by, e.g., a shallow trench isolation structure 202. The shallow trench isolation structure 202 can be made of a material including, e.g., silicon oxide or other suitable materials. In one embodiment, the semiconductor substrate 200 can be a silicon substrate, the first region I′ can be used to form a PMOS transistor, and the second region II′ can be used to form an NMOS transistor.

The first gate structure 201 in the first region I′ can include a first gate dielectric layer 203 formed on the semiconductor substrate 200 and a first gate electrode layer 205 formed on the first gate dielectric layer 203. The first gate dielectric layer 203 can be made of a material including, but not limited to, a silicon oxide, a high-K dielectric material, and/or other suitable materials. For example, the high-K dielectric material can include hafnium oxide, hafnium silicon oxide, hafnium silicon oxynitride, hafnium tantalum oxide, hafnium titanium oxide, zirconium Hafnium oxide, etc. The first gate electrode layer 205 can be made of a material including, e.g., a polysilicon or a metal such as tungsten and/or aluminum.

In one embodiment, to protect the first gate electrode layer 205, the first gate structure 201 can further include a protective layer 207 covering the first gate electrode layer 205. The first protective layer 207 can be made of a material including, for example, silicon nitride, silicon oxynitride, silicon oxide, etc.

A first sidewall spacer 209 can be formed on the sidewall of each of the first gate dielectric layer 203, the first gate electrode layer 205, and the first protective layer 207. The first sidewall spacer 209 can be made of a material including, for example, silicon nitride, silicon oxynitride, silicon oxide, etc. In some embodiments, materials used for the first protective layer 207 and the first sidewall spacer 209 can be different to facilitate a subsequent removal of the first protective layer 207. For example, the first protective layer 207 can be made of silicon nitride, while the first sidewall spacer 209 can be made of silicon oxide. In other embodiments, the first protective layer 207 and the first sidewall spacer 209 can be made of a same material.

The second gate structure 211 in the second region II′ can include a second gate dielectric layer 213 formed on the semiconductor substrate 200 and a second gate electrode layer 215 formed on the second gate dielectric layer 213. The second gate dielectric layer 213 can be made of a silicon oxide, a high-K dielectric material, and/or other suitable materials. For example, the high-K dielectric material can include hafnium oxide, hafnium silicon oxide, hafnium silicon oxynitride, hafnium tantalum oxide, hafnium titanium oxide, zirconium Hafnium oxide, etc. The second gate electrode layer 215 can be made of a material including, for example, a polysilicon or a metal such as tungsten and/or aluminum.

In one embodiment, the second gate structure 211 can further include a second protective layer 217 covering the second gate electrode layer 215. A second sidewall spacer 219 can be formed on the sidewall of each of the second gate dielectric layer 213, the second gate electrode layer 215, and the second protective layer 217. Each of the second protective layer 217 and second sidewall spacer 219 can be made of a material including, e.g., silicon nitride, silicon oxynitride, or silicon oxide. In some embodiments, the second protective layer 217 and second sidewall spacer 219 can be made of a same material. In other embodiments, the second protective layer 217 and second sidewall spacer 219 can be made of a different material. For example, the second protective layer 217 is made of silicon nitride, while the second sidewall spacer 219 is made of silicon oxide.

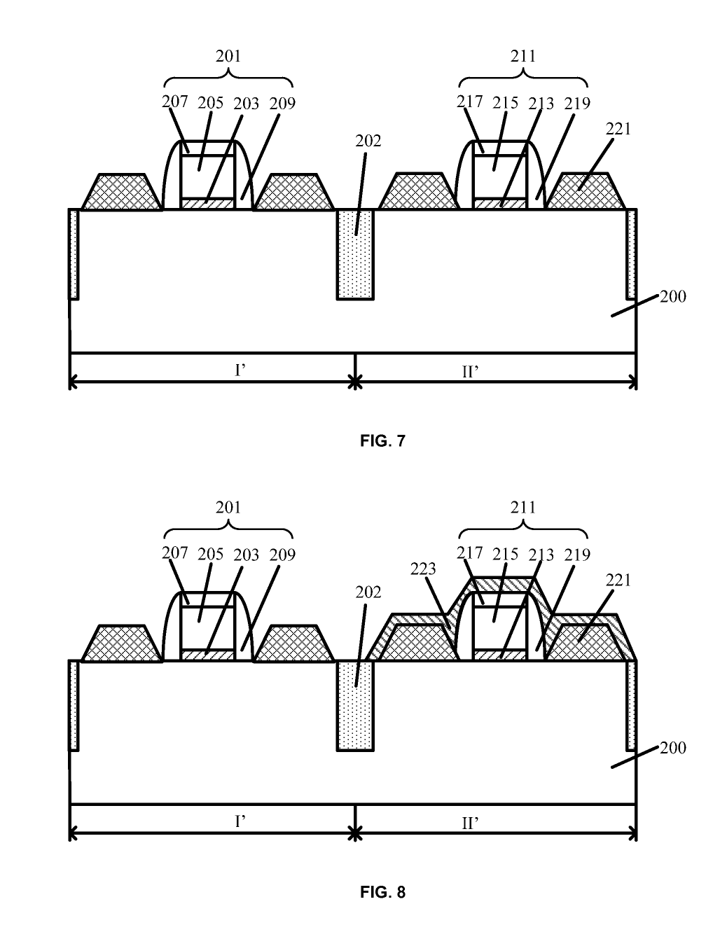

In Step 120 of FIG. 11 and referring to FIG. 7, a first stress layer 221 can be formed on the semiconductor substrate 200 on both sides of each of the first gate structure 201 and the second gate structure 211. The first stress layer 221 can be used to increase stress generated in the channel region of the second region II′.

The first stress layer 221 can be formed by a deposition process, e.g., a chemical vapor deposition, a selective epitaxial deposition, etc. In one embodiment, the first stress layer 221 can be formed using a selective epitaxial deposition process. For example, the selective epitaxial deposition can be performed at a temperature ranging from about 550° C. to about 800° C. under a pressure ranging from about 5 torr to about 20 torr. The selective epitaxial deposition can use: a SiH₄ flow rate ranging from about 30 sccm (standard cubic centimeter per minute) to about 300 sccm; a volume ratio of SiH₄ to SiH₂Cl₂ of at least about 3:2; a HCl flow rate ranging from about 50 sccm to about 200 sccm, and a H₂ flow rate ranging from about 5 sccm to about 50 sccm. The first stress layer 221 can be selectively formed on surface of the semiconductor substrate 200 and is not formed on the first gate structure 201 and/or the second gate structure 211. Accordingly, no subsequent removal steps are needed. In an exemplary embodiment, the selective epitaxial deposition can be used to form the first stress layer 221 including single crystal silicon.

In various embodiments, the first stress layer 221 can be made of a material depending on specific semiconductor devices to be formed in the second region II′. For example, when the second region II′ is used to form an NMOS transistor, the first stress layer 221 can be made of single crystal silicon carbide or single crystal silicon. When the second region II′ is used to form a PMOS transistor, the first stress layer 221 can be made of single crystal silicon germanium.

In one embodiment, the second region II′ can be used to form an NMOS transistor and the first stress layer 221 can be made of, e.g., silicon carbide. A portion of the first stress layer 221 in the first region I′ can be subsequently removed, and the remaining portion of the first stress layer 221 in the second region II′ can be used to increase tensile stress in the channel region to enhance carrier mobility of the subsequently-formed NMOS transistor.

The first stress layer 221 can have a thickness over the surface of the semiconductor substrate 200 ranging from about 200 Å to about 600 Å. A bottom surface of the first stress layer 221 can be flush with the surface of the semiconductor substrate 200. However, in other embodiments, the first stress layer 221 can be formed in the semiconductor substrate 200. For example, a shallow opening (not shown) can be formed in the semiconductor substrate 200 by an etching process to remove portions of the semiconductor material. The first stress layer can then be formed in the shallow opening.

The shallow opening can have a depth of about 1000 Å or less, i.e., a lower surface of the first stress layer 221 filled in the shallow opening can be about 1000 Å or less to the surface of the semiconductor substrate 200. In other words, a lower surface of the first stress layer in the semiconductor substrate can be about 0 Å to about 1000 Å to the surface of the semiconductor substrate and/or an upper surface of the first stress layer can be about 200 Å to about 600 Å over the surface of the semiconductor substrate. In this manner, the stress generated in the channel region of the corresponding semiconductor device in the second region II′ can be increased. Device performance of the subsequently formed CMOS transistor can be improved.

The first stress layer 221 can thus be formed on the surface of the semiconductor substrate 200 and on the sides of the first gate structure 201 and the second gate structure 211. Subsequently, a portion of the first stress layer 221 in one region can be removed, while remaining portion(s) of the first stress layer 221 can be retained in the other region. Therefore, a second stress layer can be formed on the one region after thefirst stress layer is removed from the first region I and only one mask is needed in such process in accordance with various embodiments. The manufacturing process can be significantly simplified.

In Step 130 of FIG. 11 and referring to FIG. 8, a barrier layer 223 can be formed to cover the second gate structure 211 and the first stress layer 221 in the second region II′ and to expose the first gate structure 201 and a portion of the first stress layer 221 in the first region I′.

The barrier layer 223 can protect the first stress layer 221 in the second region II' in subsequent etching process(s). The barrier layer 223 can be made of a material having an etching selectivity greater than the semiconductor substrate 200. For example, the barrier layer 223 can be made of a material such as silicon dioxide or silicon nitride. In one embodiment, the barrier layer 223 can be made of silicon nitride. The barrier layer 223 can be used as a mask for a subsequent removing process performed in the first region I′. Depending on selection of the process parameters, the barrier layer 223 of silicon nitride can be used to increase stress generated in the channel region of semiconductor device(s) formed in the second region II′. Device performance can be enhanced.

The barrier layer 223 can be formed by, e.g., a plasma deposition process using a reaction gas including ammonia, nitrogen and/or silane. Among them, ammonia can be about 10% to about 15% by volume of the total reaction gas, nitrogen can be about 2% to about 6% by volume of the total reaction gas, and silane can be about 79 to about 88% by volume of the total reaction gas. The barrier layer 223 can be formed, e.g., under a reaction pressure ranging from about 0.08 Pa to about 0.2 Pa at a reaction temperature ranging from about 300° C. to about 400° C., and using a RF power ranging from about 50 watt to about 100 watt at a RF frequency ranging from about 10 mHz to about 20 mHz. The formed barrier layer 223 can be used to provide tensile stress to the subsequently-formed NMOS transistors.

In one embodiment, to ensure protection performance of the barrier layer 223 over the first stress layer 221 in the second region II′, the barrier layer 223 can have a thickness ranging from about 200 Å to about 500 Å. Other thickness may also be used.

The barrier layer 223 can be formed by a process including, for example, forming a thin barrier film (not shown) to cover the first gate structure 201, the second gate structure 211, and the semiconductor substrate 200; forming a photoresist layer (not shown) to cover the thin barrier film in the second region II′ and to expose the first region I′; and using the photoresist layer as a mask to remove a portion of the thin barrier film in the first region I′ and to form the barrier layer 223 in the second region II′.

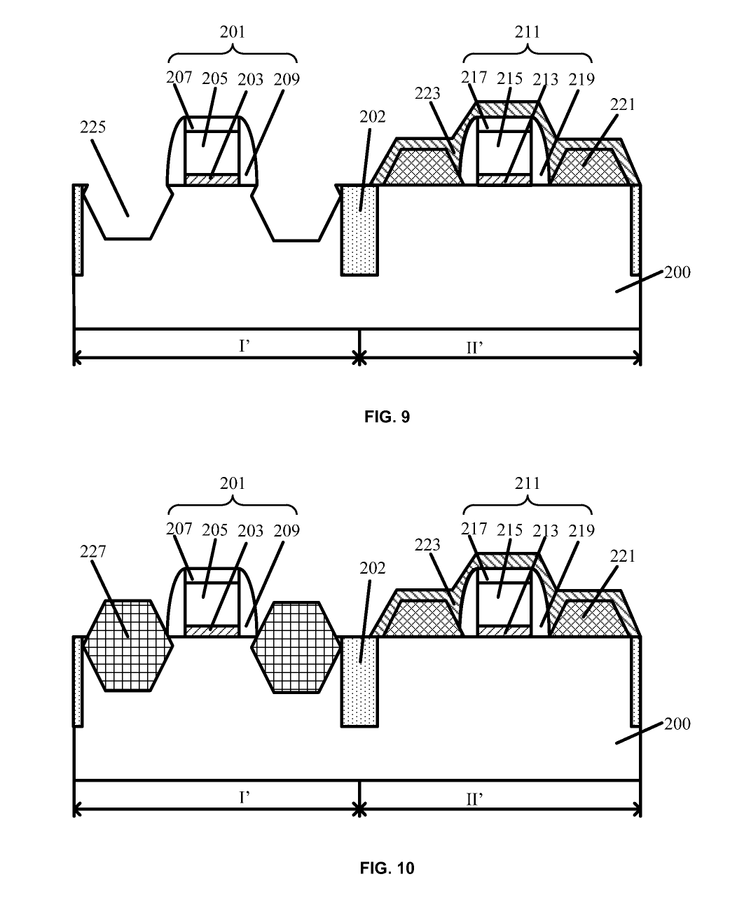

In Step 140 of FIG. 11 and referring to FIG. 9, the barrier layer 223 can be used as a mask to remove portion(s) of the first stress layer 221 in the first region I′ and to etch semiconductor substrate 200 to form a groove 225, as depicted in Step 150 of FIG. 11, on both sides of the first gate structure 201 in the first region I′.

The groove 225 can allow a second stress layer to be subsequently filled in such that the second stress layer can be formed close to the channel region to increase stress generated in the channel region of corresponding semiconductor device(s) formed in the first region I′. In various embodiments, the groove 225 formed in the first region I′ can have a cross-sectional shape including, for example, a U-shaped, sigma-shaped, polycrystalline-surface shaped, or any suitably shaped cross-section. In one embodiment, the groove 225 is sigma-shaped.

For example, a sigma-shaped groove can be formed at a temperature ranging from about 40° C. to about 60° C. using a power ranging from about 200 watts to about 400 watts at a bias voltage ranging from about 50 volts to about 200 volts. CF₄ and/or HBr can be used to etch the semiconductor substrate for about 10 seconds to about 20 seconds to form a bowl-shaped recess (not shown). This can be followed by a wet etching of the bowl-shaped recess with tetramethylammonium hydroxide (TMAH) solution having a volume concentration of from about 2% to about 20% for about 100 seconds to about 300 seconds at a temperature ranging from about 30° C. to about 60° C. A sigma-shaped groove can then be formed as shown in FIG. 9.

TMAH solution can provide high etching rate and is non-toxic, non-polluting, and easy to use. In addition, TMAH solution can have a high etching selectivity over different crystal orientations. For example, an etching rate in crystal orientation <100> and <110> can be faster than that in other orientations, for example, in direction <111>. Therefore, the formed groove 225 can be, e.g., sigma-shaped and can be close to the channel region in the first region I′ to further increase the stress generated in the channel region. In various embodiments, the sigma-shaped groove can have a depth ranging from about 400 Å to about 2000 Å in the semiconductor substrate 200 to provide suitable stress level in the channel region of the semiconductor device(s) to be formed in the first region I′.

In other embodiments where the above-mentioned shallow opening(s) (not shown) are formed in the semiconductor substrate 200 in the first and second regions and the first stress layer 221 is formed in these shallow opening(s), the groove 225 can be formed having a dimension at least the same as the corresponding shallow opening, e.g., larger than or equal to the corresponding shallow opening. This can allow the first stress layer 221 to be completely removed from the first region I′ without leaving any residues in the first region I′ and without affecting the stress generated in the channel region of the subsequently-formed semiconductor devices.

In Step 160 of FIG. 11 and referring to FIG. 10, a second stress layer 227 can be formed in the groove 225 in the first region I′. The second stress layer 227 can be used to increase stress generated in the channel region of the semiconductor device(s) located in the first region I′. The second stress layer 227 can be made of a material depending on specific semiconductor device(s) to be formed in the first region I′. When the first region I′ is used to form a PMOS transistor, materials used for the second stress layer 227 can include, e.g., silicon germanium. When the first region I′ is used to form an NMOS transistor, materials used for the second stress layer 227 can include, e.g., silicon carbide or silicon.

In an exemplary embodiment where the second stress layer 227 is made of silicon germanium, the second stress layer 227 can include a germanium content (or concentration) distribution in the second stress layer 227. For example, the germanium content can be gradually increased from an upper surface and/or a lower surface of the second stress layer 227 towards/to a middle portion of the second stress layer 227 to generate a large stress in adjacent channel region. In one embodiment, the upper surface of the second stress layer 227 can be about 200 Å to about 400 Å over the surface of the semiconductor substrate 200, e.g., to form a raised SiGe, while the lower surface of the second stress layer 227 can be about 400 Å to about 2000 Å under the surface of the semiconductor substrate 200.

The second stress layer 227 can be formed by a deposition process, e.g., a chemical vapor deposition, a selective epitaxial deposition, etc. In one embodiment, the second stress layer 227 can be formed using a selective epitaxial deposition process, for example, at a temperature ranging from about 550° C. to about 800° C. under a pressure ranging from about 5 torr to about 20 torr. The selective epitaxial deposition can use a SiH₄ flow rate ranging from about 30 sccm (standard cubic centimeter per minute) to about 300 sccm; a volume ratio of SiH₄ to SiH₂Cl₂ of at least about 3:2; a GeH₄ flow rate ranging from about 50 sccm to about 500 sccm, a HCl flow rate ranging from about 50 sccm to about 200 sccm, and a H₂ flow rate ranging from about 5 sccm to about 50 sccm.

In other embodiments, to further increase the stress generated in the channel region of the semiconductor devices formed subsequently in the first region I′, a single crystal silicon layer (not shown) can be formed to cover the second stress layer 227. As crystal lattice structures of the single crystal silicon layer and the second stress layer 227 are different, more stress can be generated in the second stress layer 227, which may further increase the stress generated in the channel region of corresponding semiconductor devices.

The second stress layer 227 can be used as source/drain regions of the subsequently-formed semiconductor devices in the first region I′. The second stress layer 227 can be doped with suitable impurity ions.

Note that although the CMOS transistor depicted in FIGS. 6-10 is illustrated having planar structures, one of ordinary skill in the art would appreciate that CMOS transistors, for example, a fin field-effect transistor (FinFET), having three dimensional (3D) structures can be encompassed in accordance with various disclosed embodiments.

In this manner, an exemplary CMOS transistor can be formed by first forming a first stress layer, e.g., using a selective epitaxial deposition process, in and/or on the semiconductor substrate in a first region and a second region. This can be followed by forming a barrier layer on surface of the first stress layer in the second region. The barrier layer can be used as a mask to etch and remove a portion of the first stress layer from the first region, while the remaining portion of the first stress layer in the second region can be retained and used in the second region. The semiconductor substrate in the first region can then be etched to form a groove in the semiconductor substrate. A second stress layer can then be formed in the groove. As disclosed, only one barrier layer is needed for forming the first stress layer (e.g., in and/or on the semiconductor substrate in the first region) and for forming the second stress layer (e.g., in and/or on the semiconductor substrate in the second region). The manufacturing process is therefore significantly simplified. In addition, the formed CMOS transistors can provide desired large stress generated in the channel region to increase carrier mobility and provide stable device performance.

During fabrication of the CMOS transistor, the first stress layer can be formed and used to cover the surface of the semiconductor substrate on both sides of each of the first gate structure and second gate structure. A barrier layer can be formed to cover the first stress layer and the second gate structure in the second region. The barrier layer can also be used as a mask to remove a portion of the first stress layer from the first region while the remaining portion of the first stress layer in the second region can be retained to increase the stress generated in the channel region of the semiconductor substrate in the second region. The barrier layer can be used as a mask to etch the semiconductor substrate in the first region to form groove(s), where the second stress layer can be formed to increase the stress generated in the channel region of the semiconductor devices in the first region. In various embodiments, the first stress layer can be formed in the semiconductor substrate. For example, a shallow opening can be formed in the semiconductor substrate by an etching process and the first stress layer can be formed in the shallow opening. The first stress layer formed in the semiconductor substrate can then be close to the channel region of the semiconductor devices in the second region to further increase the stress in the channel region of the semiconductor devices. Carrier mobility and device performance can thus be enhanced.

Other applications, advantages, alternations, modifications, or equivalents to the disclosed embodiments are obvious to those skilled in the art.

What is claimed is:

1. A method for forming a CMOS transistor comprising:
providing a semiconductor substrate including a first region having a first gate structure formed on the semiconductor substrate and a second region having a second gate structure formed on the semiconductor substrate;
forming a first stress layer on the semiconductor substrate and on sides of each of the first gate structure and the second gate structure by a selective epitaxial deposition process;
forming a barrier layer to cover the second gate structure and the first stress layer in the second region and to expose the first gate structure and a portion of the first stress layer in the first region;
removing the portion of the first stress layer in the first region using the barrier layer as a mask;
forming a groove in the semiconductor substrate on each side of the first gate structure in the first region; and
forming a second stress layer in the groove.

2. The method of claim 1, further including forming a protective layer on each of the first gate structure and the second gate structure.

3. The method of claim 1, further including forming a shallow opening in the semiconductor substrate on each side of the second gate structure in the second region, and forming the first stress layer in the shallow opening.

4. The method of claim 1, wherein an NMOS transistor is formed in the first region; the first stress layer is made of a material including silicon, silicon carbide, or a combination thereof; and the second stress layer is made of a material including silicon germanium.

5. The method of claim 4, further including forming a single crystal silicon layer on the second stress layer.

6. The method of claim 1, wherein the second stress layer is made of a material including silicon germanium and the second stress layer has a germanium content gradually increased from a lower surface and an upper surface of the second stress layer towards a middle portion of the second stress layer.

7. The method of claim 1, wherein the groove is one of U-shaped, sigma-shaped, and polycrystalline-surface shaped.

8. The method of claim 1, wherein the groove is sigma-shaped and is formed by a process including:
etching the semiconductor substrate using CF₄ and HBr for about 10 seconds to about 20 seconds to form a bowl-shaped recess in the semiconductor substrate, wherein the etching uses a power of about 200 watts to about 400 watts and a bias voltage of about 50 volts to about 200 volts at a temperature of about 40° C. to about 60° C.; and
wet etching the bowl-shaped recess to form the sigma-shaped groove in the semiconductor substrate using a tetramethyl ammonium hydroxide solution having a volume concentration ranging from about 2% to about 20% at a temperature of about 30° C. to about 60° C. for about 100 seconds to about 300 seconds.

9. The method of claim 1, wherein forming the second stress layer includes a selective epitaxial deposition process at a temperature of about 550° C. to about 800° C. and a pressure of about 5 Torr to about 20 Torr, and having a SiH₄ flow rate of about 30 sccm to about 300 sccm, a volume ratio of SiH₄ to SiH₂Cl₂ of at least 3:2, a GeH₄ flow rate of about 5 sccm to about 500 sccm, a HCl flow rate of about 50 sccm to about 200 sccm, and a H₂ flow rate of about 5 sccm to about 50 sccm.

10. The method of claim 1, further including removing the barrier layer after forming the second stress layer.

11. The method of claim 1, wherein the barrier layer material is silicon dioxide or silicon nitride.

12. The method of claim 1, wherein each of the first stress layer and the second stress layer has an upper surface over a surface of the semiconductor substrate for about 200 Å to about 600 Å.

13. The method of claim 1, wherein the first stress layer has a lower surface under a surface of the semiconductor substrate for about 0 Å to about 1000 Å, and wherein the second stress layer has a lower surface under the surface of the semiconductor substrate for about 400 Å to about 2000 Å.

14. The method of claim 1, wherein the barrier layer is formed by a plasma deposition process using a reaction gas including ammonia, nitrogen, and silane; an RF power of about 50 watts to about 100 watts; and an RF frequency of about 10 MHz to about 20 MHz under a reaction pressure of about 0.08 Pa to about 0.2 Pa at a reaction temperature of about 300° C. to about 400° C., and wherein the ammonia is about 10 to about 15% by volume of a total reaction gas, the nitrogen is about 2% to about 6 by volume of the total reaction gas, and the silane is about 79% to about 88% by volume of the total reaction gas.

15. The method of claim 1, wherein the barrier layer has a thickness of about 200 Å to about 500 Å.

16. A CMOS transistor comprising:
a semiconductor substrate including a first region having a first gate structure formed on the semiconductor substrate and a second region having a second gate structure formed on the semiconductor substrate;
a first stress layer epitaxially disposed on sides of the second gate structure; and
a second stress layer disposed on sides of the first gate structure,
wherein the first stress layer and the second stress layer are formed by a process including: forming a stress layer on the semiconductor substrate and on the sides of each of the first gate structure and the second gate structure; forming a barrier layer to cover the second gate structure and the stress layer in the second region and to expose the first gate structure and a portion of the stress layer in the first region; removing the portion of the stress layer in the first region using the barrier layer as a mask, wherein a remaining portion of the stress layer forms the first stress layer; forming a groove in the semiconductor substrate on each of the sides of the first gate structure in the first region; and forming the second stress layer in the groove.

17. The transistor of claim 16, wherein the CMOS transistor is a planar transistor or a three dimensional transistor.

18. The transistor of claim 16, wherein the first region includes an NMOS transistor; the first stress layer or the stress layer is made of a material including silicon, silicon carbide, or a combination thereof; and the second stress layer is made of a material including silicon germanium.

19. The transistor of claim 16, wherein each of the first stress layer and the second stress layer has an upper surface over a surface of the semiconductor substrate for about 200 Å to about 600 Å.

20. The transistor of claim 16, wherein the first stress layer has a lower surface under a surface of the semiconductor substrate for about 0 Å to about 1000 Å, and wherein the second stress layer has a lower surface under the surface of the semiconductor substrate for about 400 Å to about 2000 Å.
